(19) United States
(12) Patent Application Publication
(10) Pub. No.: US 2013/0292702 A1
(43) Pub. Date: Nov. 7, 2013

(54) SEMICONDUCTOR DEVICE AND METHOD FOR MANUFACTURING SAME

(71) Applicant: SUMITOMO ELECTRIC INDUSTRIES, LTD, Osaka-shi (JP)

(72) Inventor: Taku HORII, Osaka-shi (JP)

(73) Assignee: Sumitomo Electric Industries, Ltd, Osaka-shi (JP)

(21) Appl. No.: 13/856,912

(22) Filed: Apr. 4, 2013

Related U.S. Application Data
(60) Provisional application No. 61/643,721, filed on May 7, 2012.

(30) Foreign Application Priority Data
May 7, 2012 (JP) 2012-106024

(51) Int. Cl. H01L 21/28; H01L 29/16

(52) U.S. Cl. CPC H01L 21/28158; H01L 29/1608
USPC 257/77; 438/586

(57) ABSTRACT

A semiconductor device includes a substrate, a gate insulating film, a gate electrode, an interlayer insulating film, and a buffer film containing Ti and N and containing no Al, and a source electrode containing Ti, Al, and Si. In the semiconductor device, a contact hole is formed away from the gate electrode so as to extend through the interlayer insulating film. The gate insulating film is formed on a main surface of the substrate, which is formed of a plane having an off angle of not less than 50° and not more than 65° relative to a {0001} plane. The buffer film is formed in contact with a side wall surface of the contact hole. The source electrode is formed on and in contact with the buffer film and the main surface of the substrate.

### BACKGROUND OF THE INVENTION

1. Field of the Invention

The present invention relates to a semiconductor device and a method for manufacturing the semiconductor device, more particularly, a semiconductor device having improved channel mobility and achieving a stable characteristic by improving adhesion between an electrode containing aluminum and an interlayer insulating film, as well as a method for manufacturing such a semiconductor device.

2. Description of the Background Art

An electrode containing aluminum (Al) may be employed for a source electrode of a MOSFET (Metal Oxide Semiconductor Field Effect Transistor) or an emitter electrode of an IGBT (Insulated Gate Bipolar Transistor). For example, U.S. Pat. No. 6,833,562 and Japanese Patent Laying-Open No. 2000-012846 discuss a positional relation or the like in a MOSFET between such a source electrode containing Al and each of a gate electrode, a gate insulating film, and an interlayer insulating film.

In the MOSFET, the source electrode may be formed on and in contact with a surface of a substrate having an active region formed therein, and in contact with a side wall surface of an interlayer insulating film formed to surround the gate electrode on the surface. Here, if adhesion between the source electrode and the interlayer insulating film is insufficient, the source electrode comes off, thus affecting a device characteristic of the MOSFET. Further, the MOSFET is also required to achieve improved characteristic such as channel mobility.

### SUMMARY OF THE INVENTION

The present invention has been made in view of the foregoing problem, and has its object to provide a semiconductor device having improved channel mobility and achieving a stable characteristic by improving adhesion between an electrode containing aluminum and an interlayer insulating film, as well as a method for manufacturing such a semiconductor device.

A semiconductor device according to the present invention includes: a substrate made of silicon carbide; a gate insulating film formed on a surface of the substrate; a gate electrode formed on the gate insulating film; an interlayer insulating film formed on the gate insulating film to surround the gate electrode; a buffer film containing Ti and N and containing no Al; and a source electrode containing Ti, Al, and Si. In the semiconductor device, a contact hole is formed away from the gate electrode so as to extend through the interlayer insulating film and expose the surface of the substrate. The gate insulating film is formed on the surface of the substrate, the surface being formed of a plane having an off angle of not less than 50° and not more than 65° relative to a {0001} plane. The buffer film is formed on and in contact with a side wall surface of the contact hole. The source electrode is formed on and in contact with the buffer film and the surface of the substrate exposed by forming the contact hole.

Here, the expression “buffer film containing no Al” is intended to indicate a buffer film containing substantially no Al. Specifically, the buffer film is intended to indicate a buffer film in which Al is not added intentionally, and include a buffer film in which Al is contained as an impurity, for example.

In the semiconductor device according to the present invention, the source electrode is formed on and in contact with the buffer film formed in contact with the side wall surface of the contact hole extending through the interlayer insulating film, thereby improving adhesion between the source electrode and the interlayer insulating film. Further, in the semiconductor device according to the present invention, the gate insulating film is formed on the above-described surface of the substrate, which is formed of a plane having an off angle of not less than 50° and not more than 65° relative to the {0001} plane. Accordingly, a channel is formed along the plane that allows for improvement of carrier mobility. As a result, channel mobility of the semiconductor device can be improved. Hence, according to the semiconductor device in the present invention, there can be provided a semiconductor device having improved channel mobility and achieving a stable characteristic by improving adhesion between the source electrode, which is an electrode containing aluminum, and the interlayer insulating film.

In the semiconductor device, the buffer film may be made of TiN. In this way, the adhesion between the source electrode and the interlayer insulating film can be more improved.

In the semiconductor device, the buffer film may have a thickness of not less than 0.025 μm and not more than 0.15 μm. Thus, the thickness of the buffer film can be set to fall within a range necessary to improve adhesion between the source electrode and the interlayer insulating film.

A method for manufacturing a semiconductor device in the present invention includes the steps of: preparing a substrate made of silicon carbide; forming a gate insulating film on a surface of the substrate; forming a gate electrode on the gate insulating film; forming an interlayer insulating film on the gate insulating film to surround the gate electrode; forming a contact hole away from the gate electrode so as to extend through the interlayer insulating film and expose the surface of the substrate; forming a buffer film, which contains Ti and N and contains no Al, on and in contact with a side wall surface of the contact hole; and forming a source electrode, which contains Ti, Al, and Si, on and in contact with the buffer film and the surface of the substrate exposed by forming the contact hole. In the step of forming the gate insulating film, the gate insulating film is formed on the surface of the substrate, the surface being formed of a plane having an off angle of not less than 50° and not more than 65° relative to a {0001} plane.

In the method for manufacturing the semiconductor device in the present invention, the buffer film containing Ti and N is formed on and in contact with the side wall surface of the contact hole extending through the interlayer insulating film, and thereafter the source electrode containing Ti, Al, and Si is formed on and in contact with the buffer film. Thus, in the method for manufacturing the semiconductor device in the present invention, adhesion between the source electrode and the interlayer insulating film can be improved by forming the buffer film, which contains Ti and N, in advance before forming the source electrode. Further, in the method for manufacturing the semiconductor device in the present invention, the gate insulating film is formed on the above-described surface of the substrate, which is formed of a plane having an off angle of not less than 50° and not more than 65° relative to the {0001} plane. Accordingly, a channel is formed along the plane that allows for improvement of carrier mobility, thereby manufacturing a semiconductor device having improved channel mobility. Hence, according to the method for manufacturing the semiconductor device in the present invention, there can be provided a method for manufacturing a semiconductor device, by which the semiconductor device according to the present invention can be manufactured to have improved channel mobility and achieve a stable characteristic by improving adhesion between the source electrode, which is an electrode containing aluminum, and the interlayer insulating film.

In the method for manufacturing the semiconductor device, the step of forming the source electrode may include the steps of: forming a metal film in which a first metal layer, a second metal layer, and a third metal layer are stacked on one another, the first metal layer containing Ti, the second metal layer being formed on and in contact with the first metal layer and containing Al, the third metal layer being formed on and in contact with the second metal layer and containing Si; and forming the source electrode by heating the metal film. Alternatively, in the method for manufacturing the semiconductor device, the step of forming the source electrode may include the steps of: forming a metal film in which Ti, Al, and Si are mixed; and forming the source electrode by heating the metal film. In this way, the source electrode can be formed readily.

In the method for manufacturing the semiconductor device, the buffer film formed in the step of forming the buffer film may be made of TiN. In this way, the adhesion between the source electrode and the interlayer insulating film can be more improved.

In the method for manufacturing the semiconductor device, the buffer film formed in the step of forming the buffer film may have a thickness of not less than 0.025 μm and not more than 0.15 μm. Thus, the thickness of the buffer film can be set to fall within a range necessary to improve adhesion between the source electrode and the interlayer insulating film.

As apparent from the description above, according to the semiconductor device and the method for manufacturing the semiconductor device in the present invention, there can be provided a semiconductor device having improved channel mobility and achieving a stable characteristic by improving adhesion between an electrode containing aluminum and an interlayer insulating film, as well as a method for manufacturing the semiconductor device.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view showing a structure of a MOSFET.

FIG. 2 is a flowchart schematically showing a method for manufacturing the MOSFET.

FIG. 3 is a flowchart schematically showing a step of forming a source electrode.

FIG. 4 is a flowchart schematically showing a step of forming a drain electrode.

FIG. 5 is a schematic cross sectional view for illustrating the method for manufacturing the MOSFET.

FIG. 6 is a schematic cross sectional view for illustrating the method for manufacturing the MOSFET.

FIG. 7 is a schematic cross sectional view for illustrating the method for manufacturing the MOSFET.

FIG. 8 is a schematic cross sectional view for illustrating the method for manufacturing the MOSFET.

FIG. 9 is a schematic cross sectional view for illustrating the method for manufacturing the MOSFET.

FIG. 10 is a schematic cross sectional view for illustrating the method for manufacturing the MOSFET.

FIG. 11 is a schematic cross sectional view for illustrating the method for manufacturing the MOSFET.

FIG. 12 is a schematic cross sectional view for illustrating the method for manufacturing the MOSFET.

FIG. 13 is a schematic cross sectional view for illustrating the method for manufacturing the MOSFET.

FIG. 14 is an enlarged view schematically showing a structure of a first metal film in FIG. 13.

FIG. 15 is a schematic cross sectional view for illustrating the method for manufacturing the MOSFET.

### DESCRIPTION OF THE PREFERRED EMBODIMENTS

The following describes an embodiment of the present invention based on figures. It should be noted that the same or corresponding portions in the figures described below are given the same reference characters and are not described repeatedly. Further, in the present specification, an individual orientation is represented by [ ], a group orientation is represented by < >, and an individual plane is represented by ( ), and a group plane is represented by { }. In addition, a negative index is supposed to be crystallographically indicated by putting “-” (bar) above a numeral, but is indicated by putting the negative sign before the numeral in the present specification.

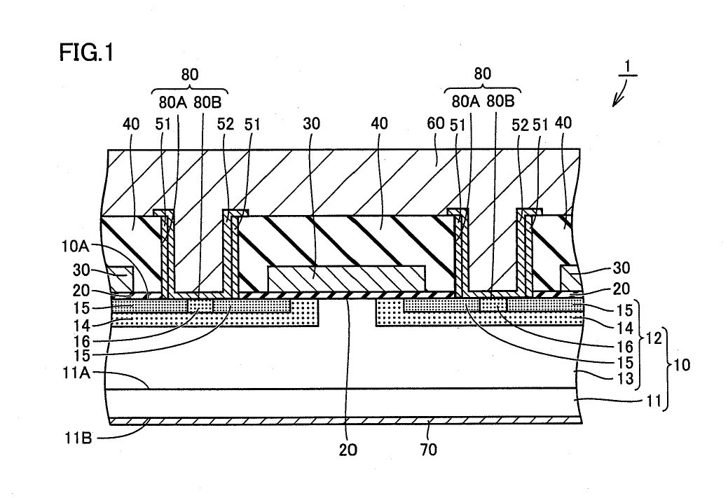

First, the following describes a structure of a MOSFET 1 serving as a semiconductor device according to the present embodiment. Referring to FIG. 1, MOSFET 1 includes a substrate 10 made of silicon carbide, gate insulating films 20, gate electrodes 30, interlayer insulating films 40, buffer films 51, source electrodes 52, a source wire 60, and a drain electrode 70. Substrate 10 includes a base substrate 11 and a semiconductor layer 12. In semiconductor layer 12, a drift region 13, body regions 14, source regions 15, and contact regions 16 are formed. Further, in MOSFET 1, contact holes 80 are formed away from gate electrodes 30 to extend through gate insulating film 20 and interlayer insulating film 40 and expose a main surface 10A of substrate 10. Further, main surface 10A of substrate 10 may be formed of a plane having an off angle of not less than 50° and not more than 65° relative to a {0001} plane.

Base substrate 11 contains an n type impurity such as N (nitrogen) and therefore has n type conductivity (first conductivity type). Drift region 13 is an epitaxial growth layer formed on a main surface 11A of base substrate 11. As with base substrate 11, drift region 13 contains an n type impurity such as N (nitrogen), and therefore has n type conductivity. The concentration thereof in drift region 13 is lower than that in base substrate 11.

Body regions 14 include main surface 10A of substrate 10, and are formed to be separated from each other in semiconductor layer 12. Each of body regions 14 contains a p type impurity such as Al (aluminum) or B (boron), and therefore has p type conductivity (second conductivity type).

Source regions 15 include main surface 10A, and are formed in body regions 14 such that they are surrounded by body regions 14. Each of source regions 15 contains an n type impurity such as P (phosphorus), and therefore has n type conductivity as with base substrate 11 and drift region 13. Further, the concentration of the n type impurity in source region 15 is higher than the concentration of the n type impurity in drift region 13.

As with source region 15, contact regions 16 include main surface 10A, are surrounded by body regions 14, and are respectively formed in body regions 14 so as to be adjacent to source regions 15. As with body region 14, each of contact regions 16 contains a p type impurity such as Al (aluminum) or B (boron) and therefore has p type conductivity. The concentration thereof in contact region 16 is higher than that in body region 14.

Each of gate insulating films 20 is made of, for example, SiO₂ (silicon dioxide), is formed to be disposed on and in contact with main surface 10A of substrate 10, and extends from the upper surface of one source region 15 to the upper surface of the other source region 15. Main surface 10A of substrate 10 is formed of a plane having an off angle of not less than 50° and not more than 65° relative to the {0001} plane.

Each of gate electrodes 30 is disposed on and in contact with gate insulating film 20, and is formed to extend from one source region 15 to the other source region 15. Gate electrode 30 is made of a conductor such as polysilicon having an impurity added therein, for example.

Interlayer insulating film 40 is made of, for example, SiO₂ (silicon dioxide), and is formed on gate insulating film 20 to surround gate electrode 30. Each of contact holes 80 has side wall surfaces 80A and a bottom surface 80B, and is formed to extend through interlayer insulating film 40 and gate insulating film 20. Further, as shown in FIG. 1, each of side wall surfaces 80A of contact hole 80 is constituted of interlayer insulating film 40 and gate insulating film 20, and bottom surface 80B thereof corresponds to the upper surfaces of source region 15 and contact region 16.

In contact hole 80, buffer film 51 is formed on and in contact with side wall surface 80A. Buffer film 51 is a film containing Ti and N and containing no Al. For example, buffer film 51 may be a film made of TiN. Alternatively, buffer film 51 may be a film made of TiW or a film made of TaN.

Source electrode 52 is formed on and in contact with buffer film 51 and main surface 10A of substrate 10 exposed by forming contact hole 80. Further, source electrode 52 is a film containing Ti, Al, and Si, for example, is made of a TiAlSi alloy.

Drain electrode 70 is formed on main surface 11B of base substrate 11 opposite to main surface 11A thereof. As with source electrode 52, drain electrode 70 is made of, for example, a TiAlSi alloy, and is electrically connected to base substrate 11.

Source wire 60 is formed to cover source electrode 52 and interlayer insulating film 40. Source wire 60 is made of a metal such as Al (aluminum), and is electrically connected to source region 15 via source electrode 52.

The following describes an operation of MOSFET 1 serving as the semiconductor device according to the present embodiment. Referring to FIG. 1, when a voltage is applied between source electrode 52 and drain electrode 70 while an applied voltage to gate electrode 30 is smaller than a threshold voltage, i.e., while it is in OFF state, a pn junction formed between body region 14 and drift region 13 is reverse-biased. Accordingly, MOSFET 1 is in the non-conductive state. Meanwhile, when gate electrode 30 is fed with a voltage equal to or greater than the threshold voltage, an inversion layer is formed in body region 14. As a result, source region 15 and drift region 13 are electrically connected to each other, whereby a current flows between source electrode 52 and drain electrode 70. In the manner described above, MOSFET 1 operates.

As described above, in MOSFET 1 according to the present embodiment, source electrode 52 is formed on and in contact with buffer film 51 formed in contact with side wall surface 80A of contact hole 80 extending through interlayer insulating film 40, thereby improving adhesion between source electrode 52 and interlayer insulating film 40. Further, in MOSFET 1, gate insulating film 20 is formed on main surface 10A of substrate 10, which is formed of a plane having an off angle of not less than 50° and not more than 65° relative to the {0001} plane. Accordingly, a channel is formed along the plane that allows for improvement of carrier mobility. As a result, channel mobility of MOSFET 1 can be improved. Thus, MOSFET 1 according to the present embodiment is a semiconductor device having improved channel mobility and achieving stable characteristic by improving adhesion between source electrode 52, which is an electrode containing aluminum, and interlayer insulating film 40.

Further, in MOSFET 1, main surface 10A of substrate 10 on which gate insulating film 20 is formed may have an off orientation that forms an angle of 5° or less relative to the <01-10> direction. The <01-10> direction is a representative off orientation in a substrate made of silicon carbide. Thus, when the angle formed by the off orientation of main surface 10A of substrate 10 and the <01-10> direction is set to fall within the above-described range, preparation of substrate 10 by forming semiconductor layer 12 on base substrate 11 through epitaxial growth can be facilitated.

Further, in MOSFET 1, main surface 10A of substrate 10 on which gate insulating film 20 is formed may have an off angle of not less than −3° and not more than +5° relative to the {03-38} plane in the <01-10> direction. Accordingly, the channel mobility of MOSFET 1 can be more improved. Here, setting the off angle at not less than −3° and not more than +5° relative to the {03-38} plane is based on a fact that particularly high channel mobility was obtained in this set range as a result of inspecting a relation between the channel mobility and the off angle.

Further, the “off angle relative to the {03-38} plane in the <01-10> direction” refers to an angle formed by an orthogonal projection of a normal line of main surface 10A to a flat plane including the <01-10> direction and the <0001> direction, and a normal line of the {03-38} plane. The sign of positive value corresponds to a case where the orthogonal projection approaches in parallel with the <01-10> direction whereas the sign of negative value corresponds to a case where the orthogonal projection approaches in parallel with the <0001> direction.

Further, in MOSFET 1, main surface 10A of substrate 10 on which gate insulating film 20 is formed more preferably has a plane orientation of substantially {03-38}, and main surface 10A further preferably has a plane orientation of {03-38}. Here, the expression “main surface 10A has a plane orientation of substantially {03-38}” is intended to encompass a case where the plane orientation of main surface 10A is included in a range of off angle such that the plane orientation can be substantially regarded as {03-38} in consideration of accuracy of slicing when preparing substrate 10. In this case, the range of off angle is, for example, a range of off angle of ±2° relative to {03-38}. Accordingly, the channel mobility of MOSFET 1 can be more improved.

Further, in MOSFET 1, main surface 10A of substrate 10 on which gate insulating film 20 is formed may be formed of a plane of carbon plane side of the silicon carbide that forms substrate 10. Accordingly, the channel mobility of MOSFET 1 can be further improved. Here, the (0001) plane of single-crystal silicon carbide of hexagonal crystal is defined as the silicon plane whereas the (000-1) plane is defined as the carbon plane. In other words, when employing the configuration in which the off orientation of main surface 10A of substrate 10 forms an angle of 5° or smaller relative to the <01-10> direction as described above, the channel mobility of MOSFET 1 can be further improved by adapting main surface 10A to correspond to a plane close to the (0-33-8) plane.

Further, in MOSFET 1, buffer film 51 may be made of TiN as described above. In this way, the adhesion between source electrode 52 and interlayer insulating film 40 can be more improved.

Further, in MOSFET 1, buffer film 51 may have a thickness of not less than 0.025 μm and not more than 0.15 μm. Thus, the thickness of buffer film 51 can be set to fall within a range necessary to improve adhesion between source electrode 52 and interlayer insulating film 40.

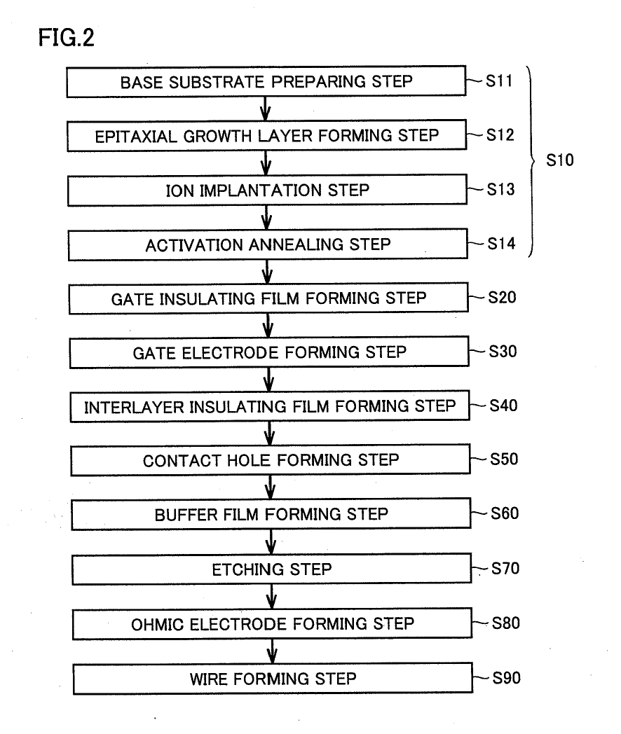

The following describes a method for manufacturing the semiconductor device in one embodiment of the present invention with reference to FIG. 1 to FIG. 15. In the method for manufacturing the semiconductor device in the present embodiment, MOSFET 1 serving as the semiconductor device according to the present embodiment is manufactured. Referring to FIG. 2, a substrate preparing step (S10) is first performed. In this step (S10), steps (S11) to (S14) described below are performed to prepare substrate 10 that is made of silicon carbide and that has main surface 10A formed of a plane having an off angle of not less than 50° and not more than 65° relative to the {0001} plane.

First, as step (S11), a base substrate preparing step is performed. In this step (S11), referring to FIG. 5, an ingot (not shown) made of, for example, 4H—SiC is sliced to prepare base substrate 11 having n type conductivity.

Next, as a step (S12), an epitaxial growth layer forming step is performed. In this step (S12), referring to FIG. 5, semiconductor layer 12 having n type conductivity is formed by epitaxial growth on main surface 11A of base substrate 11.

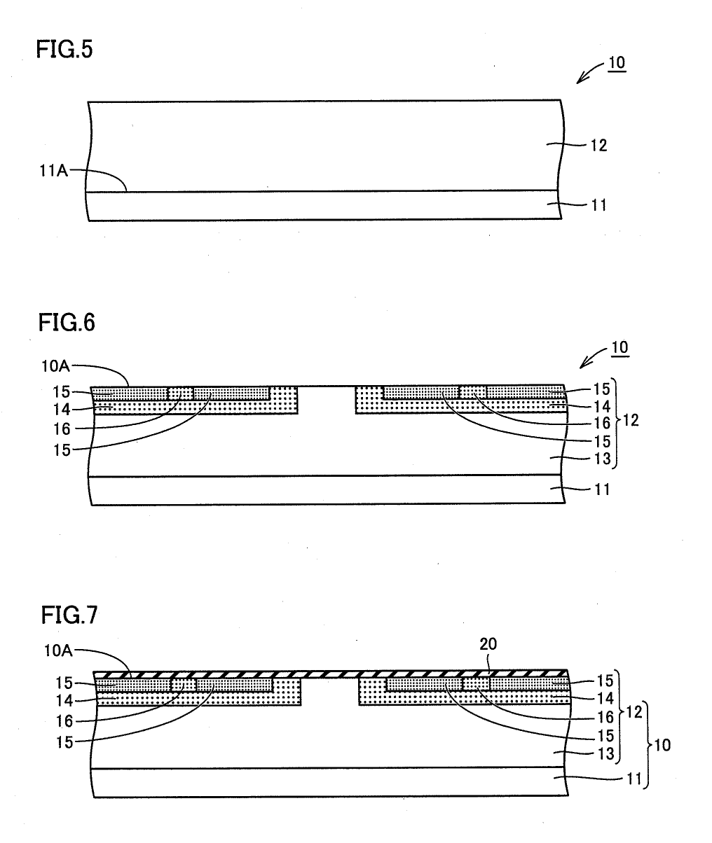

Next, as step (S13), an ion implantation step is performed. In this step (S13), referring to FIG. 6, for example, Al ions are first implanted into regions including main surface 10A of substrate 10, thereby forming body regions 14 of p type conductivity in semiconductor layer 12. Next, for example, P ions are implanted into each of body regions 14 at a depth shallower than the depth in which the Al ions have been implanted, thereby forming source region 15 of n type conductivity. Then, for example, Al ions are further implanted into body region 14, thereby forming contact region 16 adjacent to source region 15, having the same depth as that of source region 15, and having p type conductivity. Further, in semiconductor layer 12, a region in which none of body region 14, source region 15, and contact region 16 is formed serves as drift region 13.

Next, as step (S14), an activation annealing step is performed. In this step (S14), by heating substrate 10, the impurities implanted in step (S13) are activated. Accordingly, desired carriers are generated in the regions having the impurities implanted therein. In this way, by performing steps (S11) to (S14), substrate 10 is prepared in which an active region is formed by the implantation of the impurities.

Next, as a step (S20), a gate insulating film forming step is performed. In this step (S20), referring to FIG. 7, for example, by heating substrate 10 in an atmosphere containing oxygen, gate insulating film 20 made of SiO₂ (silicon dioxide) is formed to cover main surface 10A of substrate 10 which is formed of a plane having an off angle of not less than 50° and not more than 65° relative to the {0001} plane.

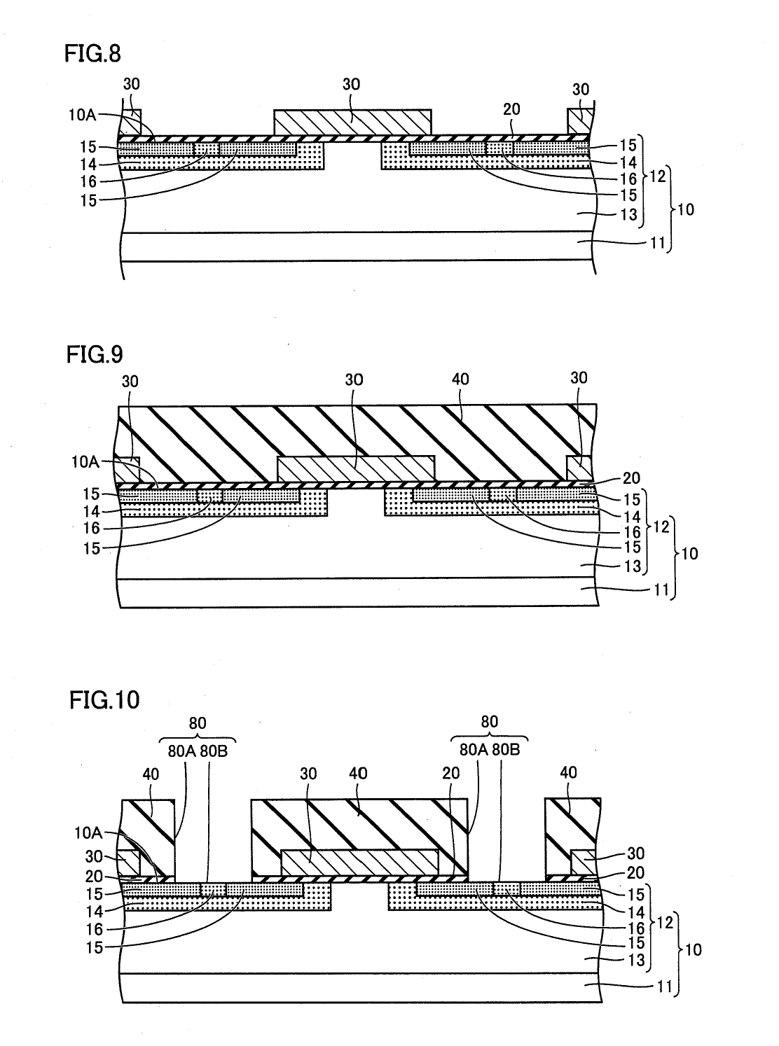

Next, as a step (S30), a gate electrode forming step is performed. In this step (S30), referring to FIG. 8, for example, an LPCVD (Low Pressure Chemical Vapor Deposition) method is employed to form, on gate insulating film 20, gate electrode 30 made of polysilicon containing an impurity.

Next, as a step (S40), an interlayer insulating film forming step is performed. In this step (S40), referring to FIG. 9, for example, a P (Plasma)-CVD method is employed to form interlayer insulating film 40 made of SiO₂ (silicon dioxide) on gate insulating film 20 such that interlayer insulating film 40 and gate insulating film 20 surround gate electrode 30.

Next, as a step (S50), a contact hole forming step is performed. In this step (S50), referring to FIG. 10, contact hole 80 is formed to have side wall surface 80A and bottom surface 80B and expose main surface 10A of substrate 10. Specifically, for example, an etching method such as RIE (Reactive Ion Etching) is employed to etch through interlayer insulating film 40 and gate insulating film 20, thereby forming contact hole 80 exposing main surface 10A of substrate 10 (the upper surfaces of source region 15 and contact region 16). Further, in this step (S50), contact hole 80 is formed away from gate electrode 30. Hence, as shown in FIG. 10, gate electrode 30 is maintained to be surrounded by gate insulating film 20 and interlayer insulating film 40.

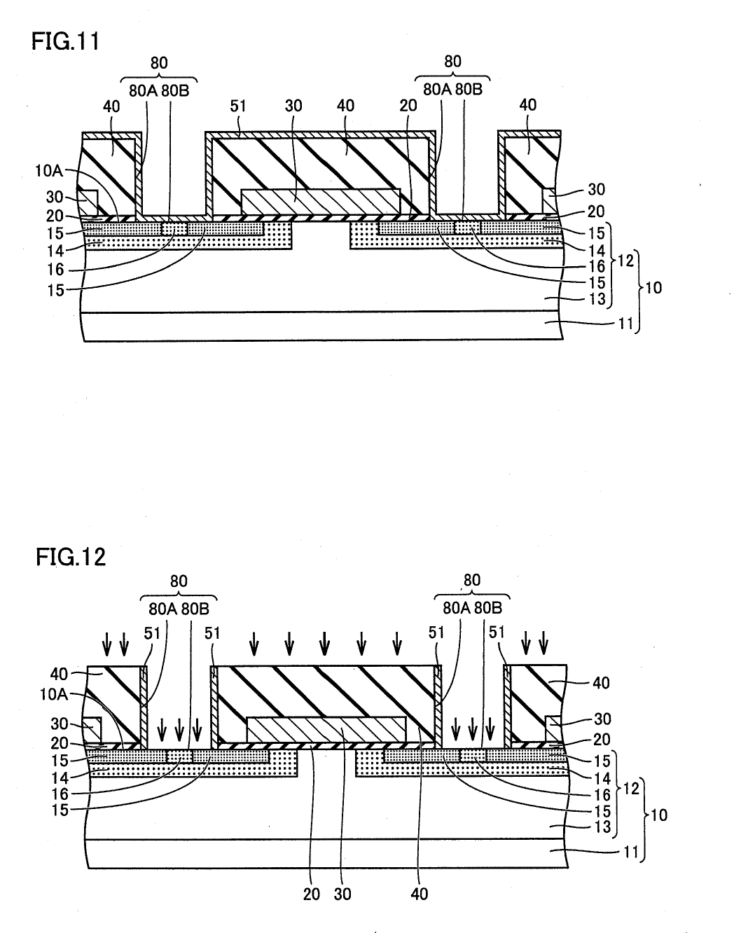

Next, as step (S60), a buffer film forming step is performed. In this step (S60), referring to FIG. 11, for example, sputtering is performed to form buffer film 51 on and in contact with side wall surface 80A and bottom surface 80B of contact hole 80 and the upper surface of interlayer insulating film 40. In this step (S60), for example, a film made of TiN may be formed as buffer film 51 containing Ti and N and containing no Al. Alternatively, as buffer film 51, a film made of TiW or a film made of TaN may be formed. Further, in this step (S60), buffer film 51 may be formed to have a thickness of not less than 0.025 μm and not more than 0.15 μm.

Next, as a step (S70), an etching step is performed. In this step (S70), as indicated by arrows in FIG. 12, dry etching is performed from the side of main surface 10A of substrate 10, thereby removing buffer film 51 from the upper surface of interlayer insulating film 40 and bottom surface 80B of contact hole 80 while buffer film 51 remains on side wall surface 80A of contact hole 80.

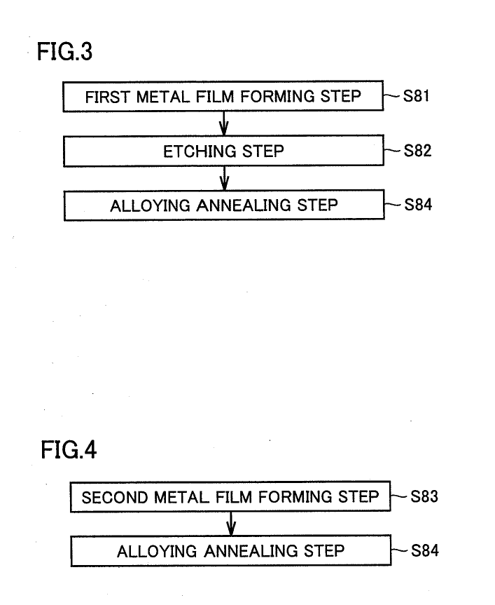

Next, as step (S80), an ohmic electrode forming step is performed. In this step (S80), referring to FIG. 3 and FIG. 4, steps (S81) to (S84) described below are performed to form source electrode 52, which contains Ti, Al, and Si, on and in contact with buffer layer 51 and main surface 10A of substrate 10 exposed by forming contact hole 80, and form drain electrode 70, which is made of, for example, the same material as that of source electrode 52, on and in contact with main surface 11B of base substrate 11.

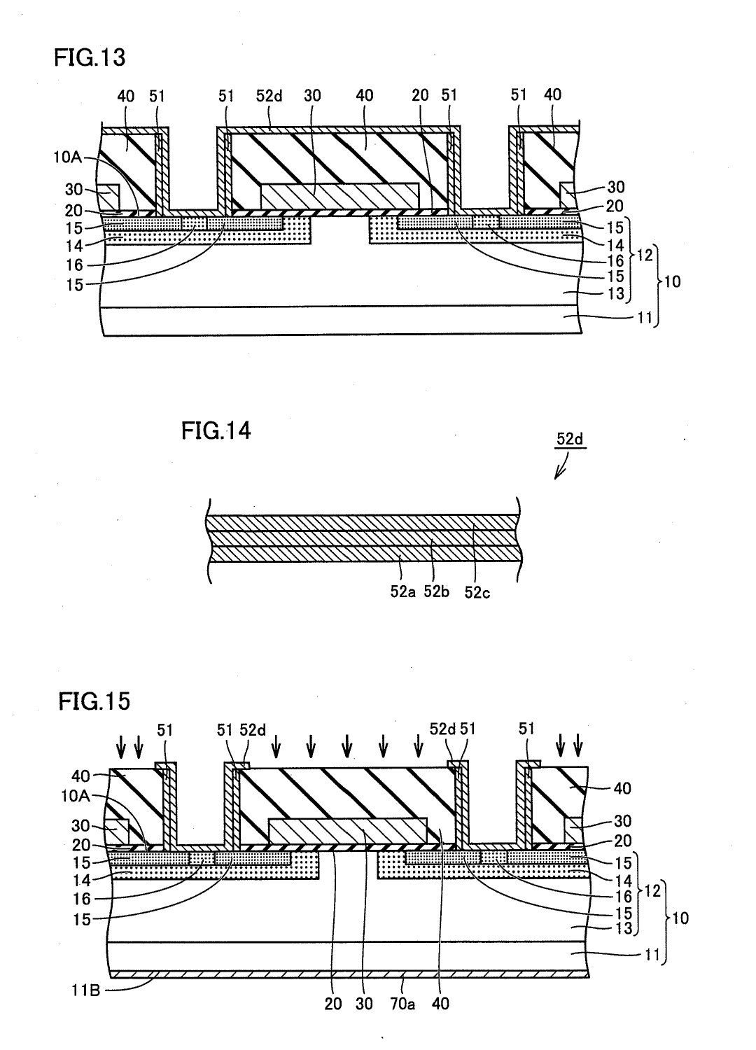

First, as step (S81), a first metal film forming step is performed. In this step (S81), referring to FIG. 13 and FIG. 14, for example, sputtering is performed to form a first metal film 52d structured to include a first metal layer 52a, a second metal layer 52b, and a third metal layer 52c stacked on one another. First metal layer 52a contains Ti. Second metal layer 52b is on and in contact with first metal layer 52a and contains Al. Third metal layer 52c is on and in contact with second metal layer 52b and contains Si. Although first metal film 52d may be formed by forming first to third metal layers 52a to 52c on one another in this step (S81) as described above, the present invention is not limited to this. For example, a first metal film 52d in which Ti, Al, and Si are mixed may be formed by simultaneously sputtering Ti, Al, and Si.

Next, as step (S82), an etching step is performed. In this step (S82), a mask (not shown) is disposed in the vicinity of contact hole 80, and then dry etching is performed from the side of main surface 10A of substrate 10 as indicated by arrows in FIG. 15, thereby mainly removing first metal film 52d from the upper surface of interlayer insulating film 40. As a result, first metal film 52d on and in contact with buffer film 51 and bottom surface 80B of contact hole 80 remains.

Next, as step (S83), a second metal film forming step is performed. In this step (S83), referring to FIG. 15, as with first metal film 52d, a second metal film 70a in which layers of Ti, Al, and Si are stacked on one another or in which Ti, Al, and Si are mixed is formed by means of sputtering on main surface 11B of base substrate 11, for example.

Next, as step (S84), an alloying annealing step is performed. In this step (S84), referring to FIG. 1, first and second metal films 52d, 70a formed in steps (S81) and (S83) are heated. Accordingly, Ti, Al, and Si, which composes first and second metal films 52d, 70a, are alloyed, thereby forming source electrode 52 and drain electrode 70 each made of the TiAlSi alloy and making ohmic contact with substrate 10. In step (S80), by thus performing steps (S81), (S82) and (S84), source electrode 52 is formed (see FIG. 3). By performing steps (S83) and (S84), drain electrode 70 is performed (see FIG. 4).

Next, as a step (S90), a wire forming step is performed. In this step (S90), referring to FIG. 1, for example, a deposition method is employed to form source wire 60, which is made of a conductor such as Al, on and in contact with source electrode 50. By performing steps (S10) to (S90), MOSFET 1 is manufactured, thus completing the method for manufacturing the semiconductor device in the present embodiment.

As described above, in the method for manufacturing the semiconductor device in the present embodiment, buffer film 51 containing Ti and N is formed on and in contact with side wall surface 80A of contact hole 80 extending through interlayer insulating film 40, and thereafter source electrode 52 containing Ti, Al, and Si is formed on and in contact with buffer film 51. Thus, in the method for manufacturing the semiconductor device in the present embodiment, adhesion between source electrode 52 and interlayer insulating film 40 can be improved by forming buffer film 51, which contains Ti and N, in advance before forming source electrode 52. Further, in the method for manufacturing the semiconductor device in the present embodiment, gate insulating film 20 is formed on main surface 10A of substrate 10, which is formed of a plane having an off angle of not less than 50° and not more than 65° relative to the {0001} plane. Accordingly, a channel is formed along the plane that allows for improvement of carrier mobility, thereby forming MOSFET 1 having improved channel mobility. Hence, according to the method for manufacturing the semiconductor device in the present embodiment, there can be manufactured MOSFET 1, which serves as a semiconductor device according to the present embodiment, having improved channel and achieving a stable characteristic by improving adhesion between source electrode 52, which is an electrode containing aluminum, and interlayer insulating film 40.

Further, in the present embodiment, in the case of an IGBT, an emitter electrode can be employed as an electrode having a function of supplying carriers, as with source electrode 52 described above, for example.

The semiconductor device and the method for manufacturing the semiconductor device in the present invention can be particularly advantageously applied to a semiconductor device, which is required to have improved channel mobility and achieve a stable characteristic by improving adhesion between an electrode containing aluminum and an interlayer insulating film, as well as a method for manufacturing such a semiconductor device.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device comprising:
a substrate made of silicon carbide;
a gate insulating film formed on a surface of said substrate;
a gate electrode formed on said gate insulating film;
an interlayer insulating film formed on said gate insulating film to surround said gate electrode;
a buffer film containing Ti and N and containing no Al; and
a source electrode containing Ti, Al, and Si,
a contact hole being formed away from said gate electrode so as to extend through said interlayer insulating film and expose said surface of said substrate,
said gate insulating film being formed on said surface of said substrate, said surface being formed of a plane having an off angle of not less than 50° and not more than 65° relative to a {0001} plane,
said buffer film being formed on and in contact with a side wall surface of said contact hole,
said source electrode being formed on and in contact with said buffer film and said surface of said substrate exposed by forming said contact hole.

2. The semiconductor device according to claim 1, wherein said buffer film is made of TiN.

3. The semiconductor device according to claim 1, wherein said buffer film has a thickness of not less than 0.025 μm and not more than 0.15 μm.

4. A method for manufacturing a semiconductor device comprising the steps of:
preparing a substrate made of silicon carbide;
forming a gate insulating film on a surface of said substrate;
forming a gate electrode on said gate insulating film;
forming an interlayer insulating film on said gate insulating film to surround said gate electrode;
forming a contact hole away from said gate electrode so as to extend through said interlayer insulating film and expose said surface of said substrate;
forming a buffer film, which contains Ti and N and contains no Al, on and in contact with a side wall surface of said contact hole; and
forming a source electrode, which contains Ti, Al, and Si, on and in contact with said buffer film and said surface of said substrate exposed by forming the contact hole,
in the step of forming said gate insulating film, said gate insulating film being formed on said surface of said substrate, said surface being formed of a plane having an off angle of not less than 50° and not more than 65° relative to a {0001} plane.

5. The method for manufacturing the semiconductor device according to claim 4, wherein the step of forming said source electrode includes the steps of:
forming a metal film in which a first metal layer, a second metal layer, and a third metal layer are stacked on one another, said first metal layer containing Ti, said second metal layer being formed on and in contact with said first metal layer and containing Al, said third metal layer being formed on and in contact with said second metal layer and containing Si; and
forming said source electrode by heating said metal film.

6. The method for manufacturing the semiconductor device according to claim 4, wherein the step of forming said source electrode includes the steps of:
forming a metal film in which Ti, Al, and Si are mixed; and
forming said source electrode by heating said metal film.

7. The method for manufacturing the semiconductor device according to claim 4, wherein said buffer film formed in the step of forming said buffer film is made of TiN.

8. The method for manufacturing the semiconductor device according to claim 4, wherein said buffer film formed in the step of forming said buffer film has a thickness of not less than 0.025 μm and not more than 0.15 μm.
